(19) United States
(12) Patent Application Publication
(10) Pub. No.: US 2010/0123117 A1
(43) Pub. Date: May 20, 2010

(54) NON VOLATILE MEMORY CELLS INCLUDING A FILAMENT GROWTH LAYER AND METHODS OF FORMING THE SAME

(75) Inventors: Ming Sun, Eden Prairie, MN (US); Xilin Peng, Bloomington, MN (US); Haiwen Xi, Prior Lake, MN (US); Michael Xuefei Tang, Bloomington, MN (US)

Correspondence Address: CAMPBELL NELSON WHIPPS, LLC, HISTORIC HAMM BUILDING, 408 SAINT PETER STREET, SUITE 240, ST. PAUL, MN, 55102, US

(73) Assignee: SEAGATE TECHNOLOGY LLC, Scotts Valley, CA (US)

(21) Appl. No.: 12/273,691

(22) Filed: Nov. 19, 2008

(51) Int. Cl. H01L 45/00

(52) U.S. Cl. 257/5; 257/2; 438/102; 257/E45.002

(57) ABSTRACT

A non volatile memory cell that includes a first electrode; a variable resistive layer disposed on the first electrode; a filament growth layer disposed on the variable resistive layer, the filament growth layer including dielectric material and metal atoms; and a second electrode. In other embodiments, a memory array is disclosed that includes a plurality of non volatile memory cells, each non volatile memory cell including a first electrode; a variable resistive layer disposed on the first electrode; a filament growth layer disposed on the variable resistive layer, the filament growth layer including clusters of a first electrically conductive atomic component interspersed in an oxidized second atomic component; and a second electrode; at least one word line; and at least one bit line, wherein the word line is orthogonal to the bit line and each of the plurality of non volatile memory cells are operatively coupled to a word line and a bit line. In still other embodiments, methods are disclosed that include forming a non volatile memory cell include forming a first electrode; forming a variable resistive layer on the first electrode; depositing a two phase alloy layer on the variable resistive layer; converting the two phase alloy layer to a filament growth layer; and depositing a second electrode on the filament growth layer, thereby forming a non volatile memory cell.

### BACKGROUND

The programmable metallization cell (PMC) and resistive random access memory (RRAM) cell are new types of memory that are candidates to eventually replace flash memory. Both PMC and RRAM can offer the benefits of longer lifetimes, lower power and better memory density. As PMC and RRAM are still being developed, there remains a need for novel or advantageous PMCs and RRAMs for use in memory applications.

### BRIEF SUMMARY

Disclosed herein is a non volatile memory cell that includes a first electrode; a variable resistive layer disposed on the first electrode; a filament growth layer disposed on the variable resistive layer, the filament growth layer including dielectric material and metal atoms; and a second electrode.

Disclosed herein is a method of forming a non volatile memory cell that includes forming a first electrode; forming a variable resistive layer on the first electrode; forming a two phase alloy layer on the variable resistive layer; converting the two phase alloy layer to a filament growth layer; and forming a second electrode on the filament growth layer, thereby forming a non volatile memory cell.

These and various other features and advantages will be apparent from a reading of the following detailed description.

### BRIEF DESCRIPTION OF THE DRAWINGS

The disclosure may be more completely understood in consideration of the following detailed description of various embodiments of the disclosure in connection with the accompanying drawings, in which:

FIG. 1 is a flowchart illustrating exemplary methods for forming a non volatile memory cell;

FIGS. 2a through 2f are cross-sectional views of a non volatile memory cell at various stages of manufacture;

FIG. 3 is a flowchart illustrating exemplary methods for forming a non volatile memory cell;

FIG. 4 is a flowchart illustrating exemplary methods for forming a non volatile memory cell;

FIG. 5 is a method involving a non volatile memory cell;

FIG. 6 is a flowchart illustrating an exemplary method for forming a non volatile memory cell;

FIG. 7 is a cross-sectional view of a non volatile memory cell that includes a regulation layer; and

FIG. 8 is a schematic perspective view of a memory array including non volatile memory cells as disclosed herein;

The figures are not necessarily to scale. Like numbers used in the figures refer to like components. However, it will be understood that the use of a number to refer to a component in a given figure is not intended to limit the component in another figure labeled with the same number.

### DETAILED DESCRIPTION

In the following description, reference is made to the accompanying set of drawings that form a part hereof and in which are shown by way of illustration several specific embodiments. It is to be understood that other embodiments are contemplated and may be made without departing from the scope or spirit of the present disclosure. The following detailed description, therefore, is not to be taken in a limiting sense.

Unless otherwise indicated, all numbers expressing feature sizes, amounts, and physical properties used in the specification and claims are to be understood as being modified in all instances by the term “about.” Accordingly, unless indicated to the contrary, the numerical parameters set forth in the foregoing specification and attached claims are approximations that can vary depending upon the desired properties sought to be obtained by those skilled in the art utilizing the teachings disclosed herein.

The recitation of numerical ranges by endpoints includes all numbers subsumed within that range (e.g. 1 to 5 includes 1, 1.5, 2, 2.75, 3, 3.80, 4, and 5) and any range within that range.

As used in this specification and the appended claims, the singular forms “a”, “an”, and “the” encompass embodiments having plural referents, unless the content clearly dictates otherwise. As used in this specification and the appended claims, the term “or” is generally employed in its sense including “and/or” unless the content clearly dictates otherwise.

Spatially related terms, including but not limited to, “lower”, “upper”, “beneath”, “below”, “above”, and “on top”, if used herein, are utilized for ease of description to describe spatial relationships of an element(s) to another. Such spatially related terms encompass different orientations of the device in use or operation in addition to the particular orientations depicted in the figures and described herein. For example, if a cell depicted in the figures is turned over or flipped over, portions previously described as below or beneath other elements would then be above those other elements.

As used herein, when an element, component or layer for example is described as being “on” “connected to”, “coupled with” or “in contact with” another element, component or layer, it can be directly on, directly connected to, directly coupled with, in direct contact with, or intervening elements, components or layers may be on, connected, coupled or in contact with the particular element, component or layer, for example. When an element, component or layer for example is referred to as begin “directly on”, “directly connected to”, “directly coupled with”, or “directly in contact with” another element, there are no intervening elements, components or layers for example.

Disclosed herein are non volatile memory cells, devices and arrays including non volatile memory cells, methods of forming non volatile memory cells and methods of using non volatile memory cells. In an embodiment, non volatile memory cells disclosed herein can be programmable metallization cells (PMCs) or resistive random access memory (RRAM) cells for example. PMCs can also be referred to as conductive bridging RAM (CBRAM), nanobridge memory, or electrolytic memory.

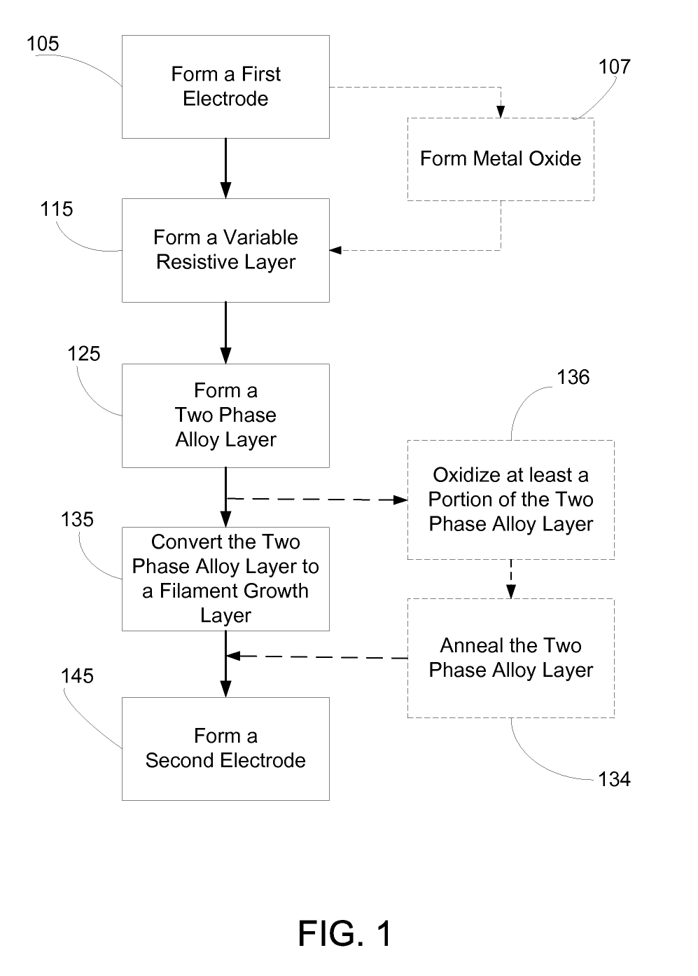

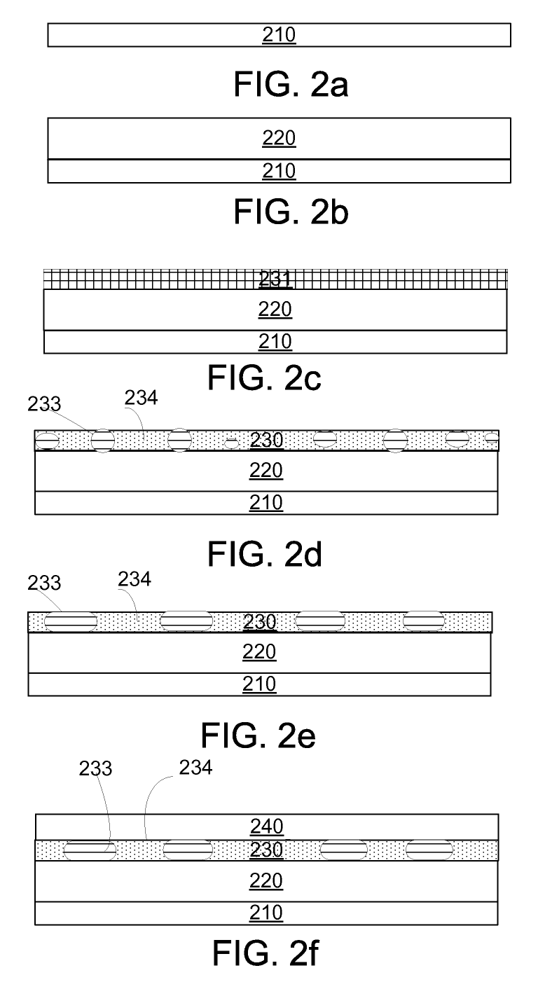

A method of forming a non volatile memory cell is illustrated in FIG. 1. Although the method depicted in FIG. 1 is depicted with a certain order, the steps discussed herein can generally be carried out in any order, other steps (both discussed herein and not discussed herein) can be added, and the order of any steps can be rearranged. A first step in an exemplary method of forming a non volatile memory cell is to form a first electrode, step 105. The first electrode can also be referred to as a bottom electrode. In an embodiment where the non volatile memory cell is a PMC, the first electrode can be an active electrode. The first electrode can be, but need not be formed on a substrate. The substrate, if utilized, can include silicon, a mixture of silicon and germanium, and other similar materials. FIG. 2a illustrates an exemplary article after completion of this first step, FIG. 2a does not depict an optional substrate, but does show the first electrode 210.

The first electrode 210 can generally be a conductive material, such as a metal. In an embodiment, the first electrode can be an active electrode. The first electrode can be made of any conductive material, including but not limited to those including, tungsten (W) or a noble metal such as gold (Au), platinum (Pt), palladium (Pd), rhodium (Rh), copper (Cu), Nickel (Ni), Silver (Ag), Cobalt (Co) or Iron (Fe). Generally, the first electrode can be formed by using known deposition methods, such as for example physical vapor deposition (PVD), chemical vapor deposition (CVD), electrochemical deposition (ECD), molecular beam epitaxy (MBE) and atomic layer deposition (ALD). In an embodiment, the first electrode can have a thickness from about 50 Å to about 5000 Å.

The next step in an exemplary method includes the step of forming a variable resistive layer 115. FIG. 2b depicts the article once the variable resistive layer 220 has been formed. As seen there, the variable resistive layer 220 is disposed on the first electrode 210. In an embodiment, the variable resistive layer 220 can be disposed directly on the first electrode 210.

Generally, a variable resistive layer can include any material whose resistance is changed by the presence or absence of one or more conductive filaments. In an embodiment, the variable resistive layer can be a PMC material. In an embodiment, the variable resistive layer can be a RRAM cell material.

In an embodiment where the variable resistive layer is a PMC material, the variable resistive layer 220 can generally be made of a material that allows ions to migrate in and out of the material. Exemplary materials include, but are not limited to, germanium selenide (GeSe) and germanium disulfide (GeS₂) materials which can also be referred to as chalcogenide glass or chalcogenide materials. Specific examples of suitable materials include, but are not limited to Ge₃Se₇, Ge₄Se₆ and Ge₂Se₃. Exemplary materials can also include, but are not limited to, oxides and sulfides such as, tungsten oxide (WO₃), silicon dioxide (SiO₂), and silver sulfide (Ag₂S) for example. Generally, the variable resistive layer of a PMC can be formed using known deposition methods, such as for example PVD, CVD, ECD, MBE and ALD. In an embodiment, the variable resistive layer of a PMC can have a thickness from about 10 Å to about 5000 Å.

In an embodiment where the variable resistive layer is a RRAM material, the variable resistive layer 220 can generally be made of a dielectric material. Specific types of RRAM materials include oxide materials for example, metal oxides. In some embodiments, the metal oxide can be a binary oxide material or a complex metal oxide material. Binary metal oxide materials can be expressed as MₓO_{y} In this formula, the characters “M”, “O”, “x” and “y” refer to metal, oxygen, a metal composition ratio, and an oxygen composition ratio, respectively. The metal “M” may be a transition metal and/or aluminum (Al). In this case, the transition metal may be nickel (Ni), niobium (Nb), titanium (Ti), zirconium (Zr), hafnium (Hf), cobalt (Co), iron (Fe), copper (Cu) and/or chrome (Cr). Specific examples of binary metal oxides that may be used as the RRAM material include, but are not limited to, CuO, NiO, CoO, ZnO, CrO₂, TiO₂, HfO₂, ZrO₂, Fe₂O₃, and Nb₂O₅. In some embodiments, the metal oxide can be any useful complex metal oxide such as, for example, pervovskites, which include complex oxide materials such as Pr_{0.7}Ca_{0.3}MnO₃, or La_{0.7}Ca_{0.}4MnO3, or SrTiO₃, or SiZrO₃, or Pb(ZrₓTi₁₋ₓ)O₃ or these oxides doped with Cr or Nb. The complex can also include LaCuO₄, or Bi₂Sr₂CaCu₂O₈.

FIG. 1 also illustrates an optional step that can, but need not, be utilized in methods as disclosed herein, the step of forming a metal oxide 107. Forming a metal oxide from a portion of the first electrode can, if carried out, enhance the mechanical stability of the interface between the first electrode and the variable resistive layer, improve the surface homogeneity of the first electrode to at least partially control filament growth when the non volatile memory cell is functioning, provide other advantages not mentioned here, or some combination thereof. Forming a metal oxide can be accomplished by oxidizing a portion of the first electrode. A portion of the material of the first electrode can be oxidized using natural oxidation processes or energy assisted oxidation processes such as plasma oxidation or UV oxidation.

The next step in an exemplary method as disclosed herein includes forming a two phase alloy layer 125. In an embodiment, the two phase alloy layer can be deposited on the variable resistive layer 220. FIG. 2c depicts an article after the two phase alloy layer 231 has been formed. As seen there, the two phase alloy layer 231 is disposed on the variable resistive layer 220. In an embodiment, the two phase alloy layer 231 can be disposed directly on the variable resistive layer 220. In an embodiment, there can be one or more layers between the variable resistive layer 220 and the two phase alloy layer 231.

The two phase alloy layer 231 generally includes at least two atomic components, a first atomic component and a second atomic component. In an embodiment, the two phase alloy can also be a material having metal inclusions. In an embodiment, a first atomic component is less readily oxidized than a second atomic component. In an embodiment, the first atomic component can be an electrically conductive atomic component. In an embodiment, a first atomic component can form a stable cation upon oxidation, the stable cation having a relatively high ionic conductivity in some media. In an embodiment, a first atomic component can be silver (Ag), copper (Cu), nickel (Ni), iron (Fe) or cobalt (Co) for example.

In an embodiment, a second atomic component is more easily oxidized than a first atomic component. In an embodiment, a second atomic component, once oxidized forms a stable oxide material. In an embodiment, a second atomic component, once oxidized, forms a material that has dielectric properties; such as aluminum (Al), zirconium (Zr), silicon (Si), gadolinium (Gd), halfnium (Hf), zinc (Zn) or titanium (Ti) for example. In an embodiment, the two phase alloy layer include silver (Ag), copper (Cu) or nickel (Ni) as the first atomic component and aluminum (Al) as the second atomic component. For example, the two phase alloy layer can be AgAlₓ, CuAlₓ or NiAlₓ where x is an integer. The thickness of the two phase alloy layer 231 can depend, at least in part, on the grain size of the first atomic component, which functions as the switch for the non volatile memory cell and thereby affects the speed at which the non volatile memory cell can function as a memory cell. In an embodiment, the two phase alloy layer 231 has a thickness of from about 5 Å to about 100 Å.

The two phase alloy layer generally comprises both of the atomic components and can, but need not be a mixture of the two components. In an embodiments where the two phase alloy layer is a mixture, the mixture can be homogeneous, mostly homogeneous, somewhat homogeneous, somewhat heterogeneous, mostly heterogeneous, heterogeneous, or any characterization in between. The two phase alloy layer can, but need not have portions with a higher amount of one atomic component and portions with a higher amount of the other atomic component. The two phase alloy layer could also be considered as a layer of one component with inclusions of the other component. For example, it could be a layer of a the second component with inclusions of the first component, for example metal atoms. The embodiment depicted in FIG. 2c shows the two phase alloy layer 231 as mostly homogenous, but it need not be so.

Generally, the relative amounts of the first atomic component and the second atomic component can depend on a number of factors, including the identities of the components. In an embodiment, there can be less (in terms of the atomic percentage) of the first atomic component than the second atomic component. In such an embodiment, when the non volatile memory cell is turned off, substantially all of the first atomic component can be oxidized (converted to a cation) and thereby move into the variable resistive layer. In an embodiment where the first atomic component is silver (Ag) and the second atomic component is aluminum (Al), the two phase alloy layer can be 10 atomic percent silver and 90 atomic percent aluminum.

In an embodiment, a method of depositing the two phase alloy layer can include two different sources, one for each of the atomic components. Deposition of two different atomic components utilizing sputtering processes can be referred to as co-sputtering. In an embodiment, a deposition method that can be utilized can utilize a single source that includes each of the atomic components. Examples of such methods include, but are not limited to sputter deposition methods such as radio frequency (RF) sputtering, ion-beam sputtering, reactive sputtering, ion-assisted deposition, high-target-utilization sputtering, and high power impulse magnetron sputtering (HIPIMS).

The next step, step 135, in an exemplary method as disclosed herein is to convert the two phase alloy layer to a filament growth layer. Because the two phase alloy layer 231 is converted into the filament growth layer 230, the materials of the two phase alloy layer can be referred to as precursor materials to the filament growth layer or the components thereof. Generally, this step can be carried out using any process than can segregate the two atomic components and oxidize one of the components. A filament growth layer can generally function to form filaments for switching the non volatile memory cell while simultaneously providing mechanical stability. A filament growth layer can include the same atomic components as the two phase alloy layer, but one of the atomic components is in an oxidized form. A filament growth layer can also generally be more heterogeneous than a two phase alloy layer from which it was formed.

FIG. 1 illustrates an exemplary process to convert the two phase alloy layer to a filament growth layer, the process includes steps 136 and 134. Step 136 includes a step of oxidizing at least a portion of the two phase alloy layer. Generally this step serves to oxidize at least a portion of one of the atomic components within the two phase alloy layer. As discussed above, the two phase alloy layer includes a first atomic component and a second atomic component and in an embodiment one of the components is more easily oxidized than the other component. Generally, the atomic component that is more easily oxidized eventually serves the mechanical stability and/or frame function of the filament growth layer and the atomic component that is harder to oxidize serves the filament growth function of the filament growth layer.

In an embodiment, the second atomic component is more easily oxidized than the first atomic component. In such an embodiment, the step 136 serves to oxidize at least a portion of the second atomic component. In an embodiment, the step 136 can serve to oxidize a majority of the second atomic component. In an embodiment, the step 136 can serve to oxidize substantially all of the second atomic component. FIG. 2d illustrates an article after step 136 has been carried out. The article in FIG. 2d illustrates that at least some of the first atomic component is at least partially separated from the second atomic component. The areas containing more of the first atomic component than second atomic component are referred to in FIG. 2d as first atomic component areas 233 and the areas with more of the second atomic component than first atomic component are referred to in FIG. 2d as second atomic component areas 234.

Oxidation can be carried out using natural oxidation or energy assisted oxidation methods. Generally, natural oxidation methods can include anodizing the two phase alloy layer in an acidic solution under a voltage. Specifically, selective oxidation by potential controlled anodization can be utilized. Energy assisted natural oxidation methods can include, but are not limited to, plasma oxidation and UV oxidation for example.

Once the two phase alloy layer has been oxidized, at least a portion of the second atomic component will exist in an oxidized form. In an embodiment, once the two phase alloy layer has been oxidized, a majority of the second atomic component will exist in an oxidized form. In an embodiment, once the two phase alloy layer has been oxidized, substantially all of the second atomic component will exist in an oxidized form. The oxidized version of the second atomic component can generally have dielectric properties, and can be referred to as a dielectric material. In an embodiment, the second atomic component can be the precursor or precursor material of the dielectric material included in a filament growth layer.

For exemplary purposes, where the second atomic component is aluminum (Al), at least a portion of it will exist as alumina (Al₂O₃) after oxidation; where the second atomic component is zirconium (Zr) at least a portion of it will exist as zirconia (ZrO₂) after oxidation; where the second atomic component is silicon (Si), at least a portion of it will exist as silica or silicon dioxide (SiO₂) after oxidation; where the second atomic component is gadolinium (Gd) at least a portion of it will exist as gadolinium oxide (Gd₂O₃) after oxidation; where the second atomic component is halfnium (Hf) at least a portion of it will exist as halfnium oxide (HfO₂) after oxidation; where the second atomic component is zinc (Zn), at least a portion of it will exist as zinc oxide (ZnO₂) after oxidation; where the second atomic component is titanium (Ti), at least a portion of it will exist as titania or titanium dioxide (TiO₂) after oxidation.

The next step in an exemplary method for converting the two phase alloy layer to a filament growth layer includes step 134, annealing the two phase alloy layer. Generally, annealing causes at least one of the two atomic components in the two phase alloy layer to diffuse or migrate, ultimately leading to portions of the two phase alloy layer that have a higher concentration of the first atomic component and portions that have a higher concentration of the second atomic component. The two phase alloy layer can be somewhat heterogenous before annealing, but generally, the step of annealing will increase the homogeneity. In an embodiment oxidizing the two phase alloy before annealing, in an embodiment to oxidize one component but not the other, serves to ensure that a solid solution of the two components will not be created. Annealing before oxidizing could case both atomic components to melt, but if one is oxidized, the oxidized component will generally not melt and the unoxidized component can be easily segregated from the oxidized component.

In an embodiment, annealing can form areas where substantially only the first atomic component exists and areas where substantially only the second atomic component exists. FIG. 2e depicts an article after an annealing step 134 has taken place. As seen in FIG. 2e, the two phase alloy layer, after annealing, includes first atomic component area 233 illustrated as the spheres within the layer; and second atomic component area 234 illustrated as the material in which the spheres are dispersed or the layer. The first atomic component areas 233 need not have a constant size or shape, and need not be homogeneously dispersed in the second atomic component area 234. The second atomic component areas 234 can, but need not be a substantially continuous material. The first atomic component before annealing, can be considered the precursor or precursor material of metal atoms included in a filament growth layer.

Generally, the step of annealing can be carried out by heating the two phase alloy layer. In an embodiment, the step of annealing can be carried out by heating the two phase alloy layer to a temperature that allows at least a portion of the first atomic component to migrate within the second atomic component. In an embodiment, the step of annealing can be carried out by heating the two phase alloy layer to a temperature that allows a majority of the first atomic component to migrate within the second atomic component. In an embodiment, the step of annealing can be carried out by heating the two phase alloy layer to a temperature that allows at least a portion of the first atomic component and at least a portion of the second atomic component to migrate. In an embodiment, the step of annealing can be carried out by heating the two phase alloy layer to a temperature that allows a majority of the first atomic component and a majority of the second component to migrate. In an embodiment, the step of annealing can be carried out by heating the two phase alloy layer to a temperature below the melting point of the alloy but above room temperature. Heating the two phase alloy layer can be carried out using known methods. Exemplary heating techniques can include localized heating of at least the two phase alloy layer or heating of the entire article. Exemplary heating techniques include, but are not limited to, infrared (IR) heating and convection heating for example.

The filament growth layer (the converted two phase alloy layer) can generally have a structure that includes clusters or areas of first atomic components interspersed in oxidized second atomic component. In an embodiment, the filament growth layer includes a dielectric material and metal atoms or metal atom clusters. The clusters or areas of first atomic components, which are depicted schematically as the first atomic component areas 233 in FIG. 2d can be dispersed in any fashion (i.e. random, somewhat random, somewhat uniform, uniform or any characterization in between) within the second atomic component areas 234. In an embodiment, the second atomic component areas 234 can generally form a continuous phase in which the first atomic component areas 233 are dispersed.

The next step in an exemplary method includes the step 145 of forming the second electrode. The second electrode can also be referred to as a top electrode. In an embodiment where the non volatile memory cell is a PMC, the second electrode can be an inert electrode. The second electrode is generally disposed on the filament growth layer. In an embodiment, the second electrode is disposed directly on the filament growth layer. FIG. 2f illustrates an exemplary article after formation of a second electrode 240.

The second electrode 240 can generally be a conductive material, such as a metal. In an embodiment, the second electrode can be an inert electrode. The second electrode can be made of any conductive material, including but not limited to, tungsten (W) or a noble metal such as gold (Au), platinum (Pt), palladium (Pd) or rhodium (Rh). Generally, the second electrode can be formed using known deposition methods, such as for example physical PVD, CVD, ECD, MBE and ALD. In an embodiment, the second electrode can have a thickness from about 50 Å to about 5000 Å.

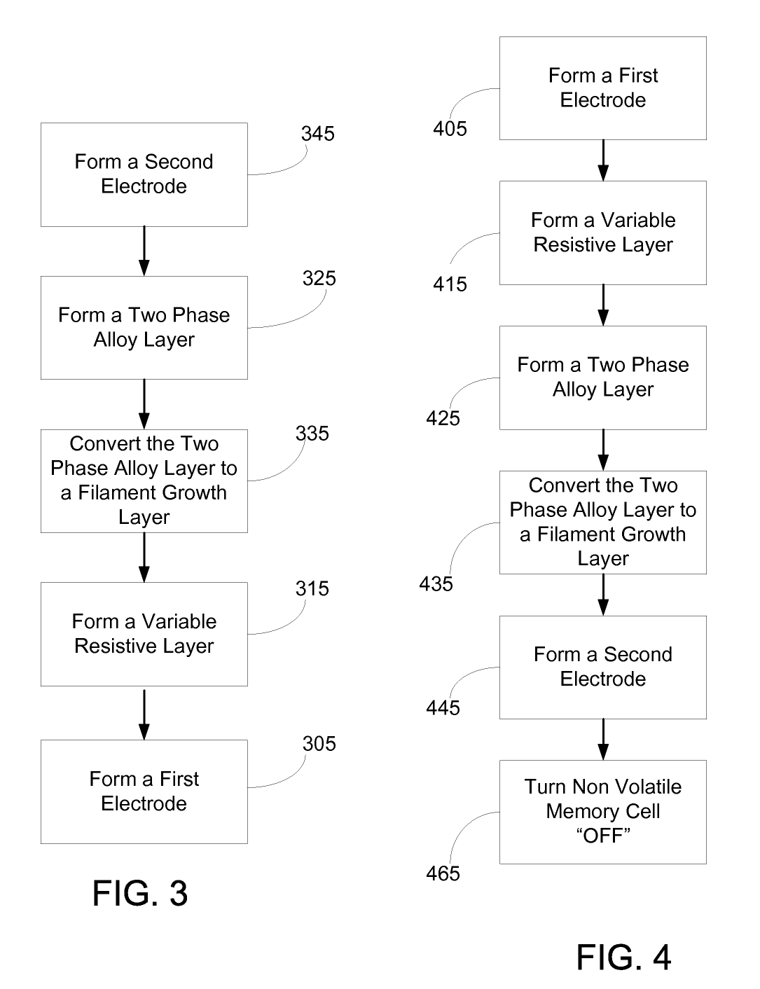

Methods as disclosed herein can also be carried out in orders other than that discussed above with respect to FIG. 1. A non-limiting example of such an order is depicted in FIG. 3. The exemplary method depicted in FIG. 3 begins with step 345, forming a second electrode (for example a top electrode, also referred to as an inert electrode in an embodiment that is a PMC), followed with step 325, forming a two phase alloy layer, then step 335, converting the two phase alloy layer to a filament growth layer, then step 315, forming a variable resistive layer and then step 305, forming a first electrode (for example a bottom electrode, also referred to as an active electrode in an embodiment that is a PMC).

Another exemplary method involving a non volatile memory cell is illustrated in FIG. 4. The method exemplified in FIG. 4 includes the steps discussed earlier; step 405, forming a first electrode, step 415, forming a variable resistive layer, step 425 forming a two phase alloy layer, step 435, converting the two phase alloy layer to a filament growth layer, and step 445, forming a second electrode (it should also be noted that these steps could have a different order, for example, the order exemplified in FIG. 3). The method depicted in FIG. 4 also includes step 465, turning the non volatile memory cell “off”. Non volatile memory cells, such as PMCs and RRAMs as disclosed herein once formed, will initially be in a low resistance state, which is generally consider “on”. Although it is not necessary, the non volatile memory cell can be turned “off” before its use as a memory cell is begun.

The optional step of turning the cell “off” can function to initially switch the non volatile memory cell from the low resistance state to the high resistance state. When a positive bias is applied to the second electrode (e.g. an inert electrode in a PMC), the first atomic component (e.g. the metal atoms) will be oxidized and forced into the variable resistive layer. This will leave gaps in the filament growth layer where the first atomic component was located, these gaps function to change the non volatile memory cell to the high resistance state.

If the optional step of turning the cell “off” is undertaken, switching the non volatile memory cell can be accomplished as is generally known. When a positive bias is applied to the first electrode (e.g. the inert electrode in a PMC), the oxidized first atomic component (e.g. the metal atoms, which may be metal cations now) in the variable resistive layer and perhaps some from the first electrode (e.g. the active electrode in a PMC) flow towards the second electrode through initial two phase alloy layer (filament growth layer) and are reduced thereby (fill the gaps again). After a short period of time the reduced flowing ions in the filament growth layer short the regions between the two electrodes, which can be measured to indicate that the “writing” process is complete.

Reading the non volatile memory cell utilizes a small voltage applied across the cell. If the linked first metal filament clusters are present in that cell, the resistance will be low, leading to higher current, which is generally read as a “1”. If there are no metal filaments present or the linkage or the superionic clusters is broken, the resistance is higher, leading to low current, which is generally read as a “0”.

Erasing the cell can be carried out in the same way as the initial step of turning the cell “off”, e.g. apply a positive bias to the second electrode. The metal ions will migrate away from the filament growth layer, back into the variable resistive layer, and eventually to the now negatively-charged first electrode. This breaks the linkage of the cell and increases the resistance of the variable resistive layer.

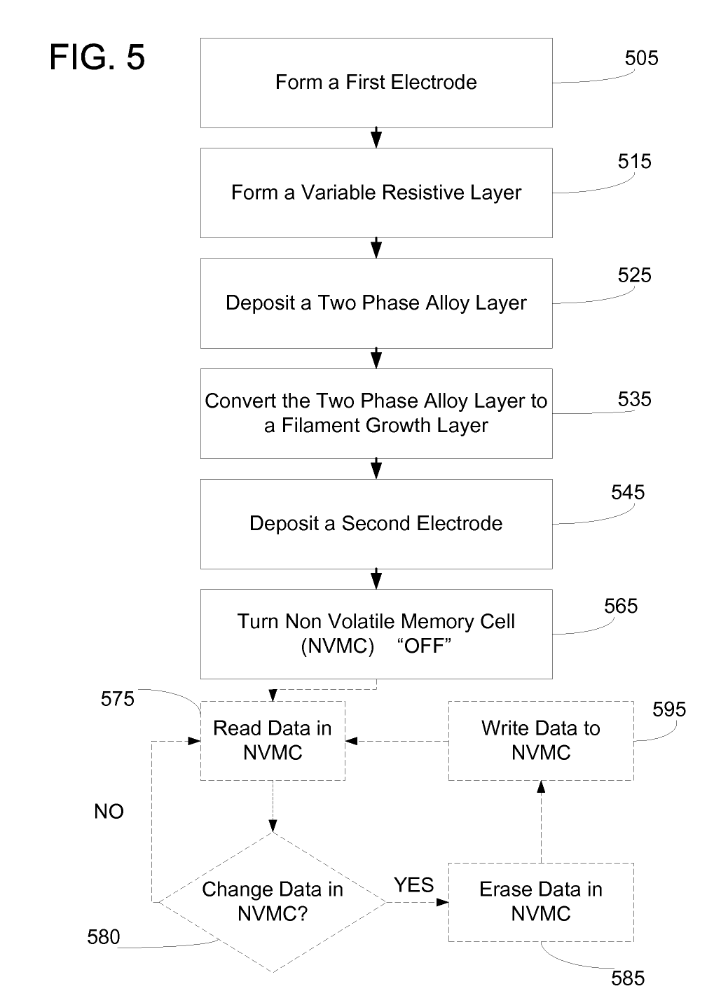

FIG. 5 illustrates a method that includes optional steps of reading the data in the non volatile memory cell, step 575 and if the data in the non volatile memory cell is to be changed (decision box 580), then erasing the data in the non volatile memory cell, step 585, and writing data to the non volatile memory cell, step 595. The steps of reading the non volatile memory cell; erasing the non volatile memory cell and writing data to the non volatile memory cell can be accomplished as discussed above and can be carried out numerous times and in a number of different orders on a non volatile memory cell. Once data has been written to the non volatile memory cell, step 595, the loop of reading the data (step 575) and deciding if it should be changed (decision box 580) can be entered again based on commands from a host.

When a non volatile memory cell as disclosed herein is in the “off”, or high resistance state, there can be a high concentration of oxidized first atomic components (e.g., metal ions) in the variable resistive layer. The concentration gradient of the metal ions can cause the metal ions to diffuse into the filament growth layer that now contains gaps where the first atomic component previously was located. This could be exacerbated by current leakage through the non volatile memory cell, which would tend to reduce the metal ions making them more likely to diffuse into the dielectric material of the filament growth layer. These conditions can cause data loss in a non volatile memory cell, a problem that is referred to as retention.

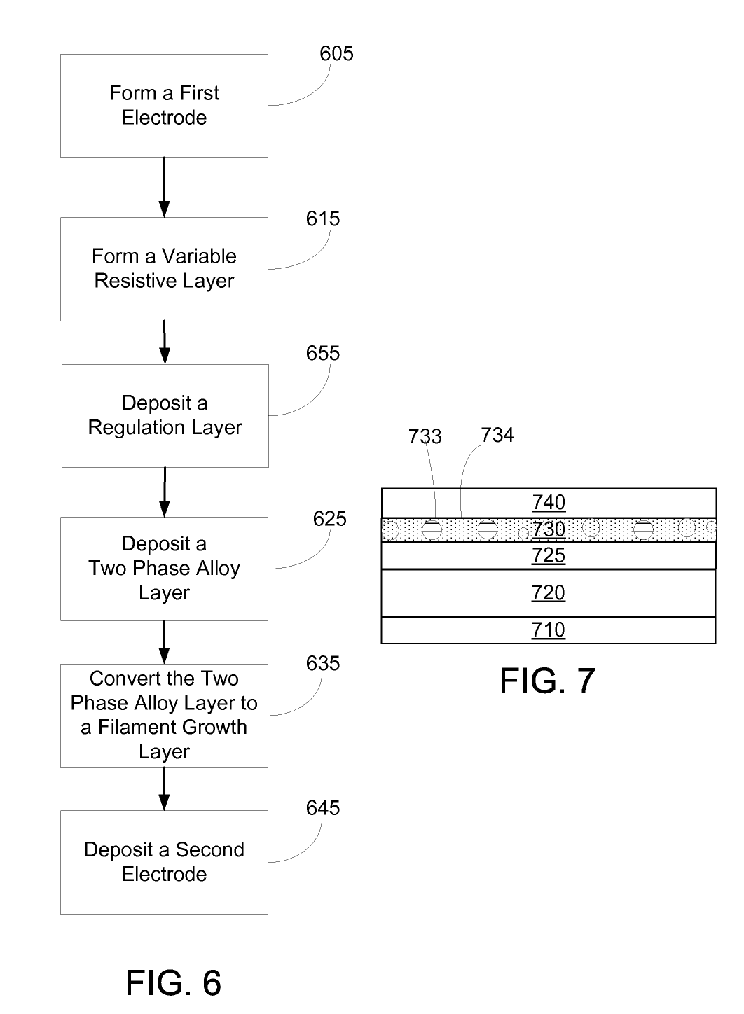

Another embodiment of a non volatile memory cell disclosed herein can be more advantageous in addressing retention issues as discussed above. Such an embodiment can be useful in PMCs or RRAMs. FIG. 6 illustrates a method of forming such a non volatile memory cell (the article formed thereby is illustrated when completed by FIG. 7). This exemplary method includes the previously discussed steps of forming a first electrode, step 605, forming a variable resistive layer, step 615, depositing a two phase alloy layer, step 625, converting the two phase alloy layer to a filament growth layer, step 635 and depositing a second electrode, step 645. This exemplary method also includes step 655, depositing a regulation layer, which is carried out after step 615, forming a variable resistive layer and before step 625, depositing a two phase alloy layer. It should also be noted that this method can also be carried out in orders other than this, for example, in reverse order (similar to the differences in FIG. 3 and FIG. 1).

The regulation layer 725 shown in FIG. 7 can generally function to impede metal cations from migrating from the variable resistive layer 720 into the filament growth layer 730. This can be advantageous because it enhances retention of data stored in a non volatile memory cell as disclosed herein. For example, when a positive bias is applied to the non volatile memory cell, the first atomic component will be oxidized and forced into the variable resistive layer 720, which is referred to as the high resistance state. The oxidized, cationic first atomic components or the reduced atomic components (the metal atoms) can migrate within the variable resistive layer and both can migrate into the filament growth layer and eventually form ohmic contacts with the second electrode 740. This can be a more significant problem with the reduced atomic components (i.e. the metal atoms). When this happens, the non volatile memory cell can change from the high resistance state to the low resistance state, which will change the data state from a “0” to a “1”. This situation can be referred to as a problem with retention.

The regulation layer 725 can impede the reduced and/or cationic first atomic components from migrating out of the variable resistive layer 720. Electrical properties of the regulation layer 725 can afford this advantage. The regulation layer 725 can include a material that has both ionic and electrical conductivity. In an embodiment, the regulation layer can be made of a material that has an ionic conductivity which is less conductive than that of the variable resistive layer. In an embodiment, the regulation layer can be made of a single phase material which could include silver iodide (AgI), copper iodide (CuI₂), copper tellurium (CuTe), germanium silver sulfide (GeₓS_{y}Ag_{z}), silver tellurium (Ag₂Te), or silver sulfide (Ag₂S). In an embodiment, the regulation layer can be the rate determining material for the ionic diffusion rate. For example, during the programming of the non volatile memory cell, the cell will be under a bias, and at that time, the low ionic diffusion may not be a concern. However, during an idle state (where retention is important), the lower ionic conductivity of the regulation layer could impede or even stop diffusion of the metal ions out of the variable resistive layer. In an embodiment, the regulation layer would also be able to impede or even stop diffusion of metal atoms out of the variable resistive layer. Impeding migration of reduced and/or oxidized metal ions out of the variable resistive layer can lead to less metal ions in the filament growth layer, which will make it harder to form reduced metal filaments through current leakage in the cell.

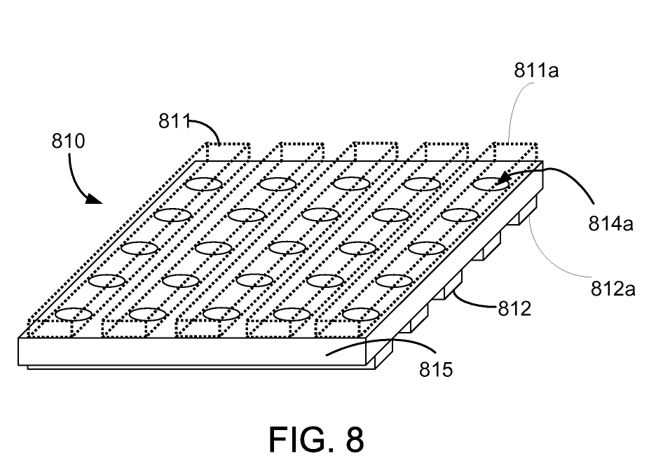

Also disclosed herein are memory arrays that include non volatile memory cells as disclosed herein. FIG. 8 illustrates an array 810 having a plurality of word lines 811 and bit lines 812 that may be orthogonal to word lines 811. An exemplary word line 811a and bit line 812a are operatively connected to a non volatile memory cell 814a. The non volatile memory cell 814a may be part of a non volatile memory cell structure 815 which can include a plurality of non volatile memory cells 814, or can have a similar layered structure across the entirety of the non volatile memory cell structure 815, with non volatile memory cells 814 being defined only by the intersection of the word lines 811 and the bit lines 812. The exemplary memory array 810 is a crosspoint array structure. A select device, such as diode or transistor, although not pictured in this figure, may be present at each crosspoint.

Non volatile memory cells as disclosed herein can be included in stand alone devices or can be integrated or embedded in devices that utilize the non volatile memory cells, including but not limited to microprocessors (e.g., computer systems such as a PC e.g., a notebook computer or a desktop computer or a server) microcontrollers, dedicated machines such as cameras, and video or audio playback devices.

Thus, embodiments of NON VOLATILE MEMORY CELLS INCLUDING A FILAMENT GROWTH LAYER AND METHODS OF FORMING THE SAME are disclosed. The implementations described above and other implementations are within the scope of the following claims. One skilled in the art will appreciate that the present disclosure can be practiced with embodiments other than those disclosed. The disclosed embodiments are presented for purposes of illustration and not limitation, and the present disclosure is limited only by the claims that follow.

What is claimed is:

1 A non volatile memory cell comprising:
a first electrode;
a variable resistive layer disposed on the first electrode;
a filament growth layer disposed on the variable resistive layer, the filament growth layer comprising dielectric material and metal atoms; and
a second electrode.

2. The non volatile memory cell according to claim 1, wherein the dielectric material is chosen from the group consisting of: alumina (Al₂O₃), zirconia (ZrO₂), silicon dioxide (SiO₂), gadolinium oxide (Gd₂O₃), halfnium oxide (HfO₂), zinc oxide (ZnO₂) and titanium oxide (TiO₂).

3. The non volatile memory cell according to claim 1, wherein the metal atoms are chosen from the group consisting of: silver (Ag), copper (Cu), nickel (Ni), Cobalt (Co), and Iron (Fe).

4. The non volatile memory cell according to claim 1, wherein the dielectric material and the metal atoms are formed from a two phase alloy.

5. The non volatile memory cell according to claim 4, wherein the two phase alloy is at least partially oxidized and annealed to form the dielectric material and the metal atoms.

6. The non volatile memory cell according to claim 1, wherein the dielectric material forms a continuous phase in the filament growth layer and the metal atoms are formed into clusters that are dispersed within the dielectric material.

7. The non volatile memory cell according to claim 1 further comprising a regulation layer positioned between the variable resistive layer and the filament growth layer.

8. The non volatile memory cell according to claim 7, wherein the regulation layer comprises an electrically conductive material that has a lower ionic conductivity than that of the variable resistive layer.

9. The non volatile memory cell according to claim 8, wherein the regulation layer comprises silver iodide (AgI), copper iodide (CuI₂), silver sulfide (Ag₂S), copper sulfide (Cu₂S), copper tellurium (CuTe) and germanium silver sulfide (GeSAg).

10. The non volatile memory cell according to claim 1, wherein the variable resistive layer is a dielectric layer and the nonvolatile memory cell is a resistive random access memory (RRAM) cell.

11. The non volatile memory cell according to claim 1, wherein the variable resistive layer is an electrolyte layer and the nonvolatile memory cell is a programmable metallization cell (PMC).

12. The non volatile memory cell according to claim 11, wherein the first electrode is an active electrode and the second electrode is an inert electrode.

13. A method of forming a non volatile memory cell comprising:
forming a first electrode;
forming a variable resistive layer on the first electrode;
depositing a two phase alloy layer on the variable resistive layer;
converting the two phase alloy layer to a filament growth layer; and
depositing a second electrode on the filament growth layer, thereby forming the non volatile memory cell.

14. The method according to claim 13 wherein the step of depositing the two phase alloy layer comprises a co-sputter deposition method or a single target alloy deposition method.

15. The method according to claim 13, wherein the two phase alloy deposited is chosen from the group consisting of: AgAlₓ, CuAlₓ and NiAlₓ.

16. The method according to claim 13, wherein the step of converting the two phase alloy layer into the filament growth layer comprises:
at least partially oxidizing the two phase alloy layer; and
annealing the two phase alloy layer.

17. The method according to claim 16, wherein the step of annealing comprises heating the two phase alloy layer and functions to at least partially segregate one element of the two phase alloy from the other element of the two phase alloy.

18. The method according to claim 16, wherein at least partially oxidizing the two phase alloy layer includes use of plasma oxidation, UV oxidation, or a combination thereof.

19. The method according to claim 16, wherein the filament growth layer comprises a dielectric material and metal atoms.

20. The method according to claim 19 further comprising turning the non volatile memory cell off by applying a positive voltage to the first electrode.

21. The method according to claim 16 further comprising forming a regulation layer on the variable resistive layer before the two phase alloy layer is deposited.

22. A memory array comprising:
a plurality of non volatile memory cells, each non volatile memory cell comprising:
a first electrode;
a variable resistive layer disposed on the first electrode;
a filament growth layer disposed on the variable resistive layer, the filament growth layer comprising clusters of a first electrically conductive atomic component interspersed in an oxidized second atomic component; and
a second electrode;
at least one word line; and
at least one bit line,
wherein the word line is orthogonal to the bit line and each of the plurality of non volatile memory cells are operatively coupled to a word line and a bit line.
